(19) United States
(12) Patent Application Publication
(10) Pub. No.: US 2025/0048938 A1
(43) Pub. Date: Feb. 6, 2025

(54) COMPUTING DEVICE

(71) Applicant: KABUSHIKI KAISHA TOSHIBA, Tokyo (JP)

(72) Inventors: Hayato GOTO, Kawasaki Kanagawa (JP); Tamio KAWAGUCHI, Kawasaki Kanagawa (JP); Noritsugu SHIOKAWA, Yokohama Kanagawa (JP); Yinghao HO, Kawasaki Kanagawa (JP)

(73) Assignee: KABUSHIKI KAISHA TOSHIBA, Tokyo (JP)

(21) Appl. No.: 18/432,810

(22) Filed: Feb. 5, 2024

(30) Foreign Application Priority Data
Aug. 3, 2023 (JP) 2023-127112

(51) Int. Cl. H10N 69/00; G06N 10/40; H01L 23/00; H01L 25/065

(52) U.S. Cl. CPC H10N 69/00; G06N 10/40; H01L 24/08; H01L 24/48; H01L 24/49; H01L 25/0655; H01L 2224/08145; H01L 2224/48091; H01L 2224/48137; H01L 2224/49111; H01L 2224/49176

(57) ABSTRACT

According to one embodiment, a computing device includes an element section. The element section includes a first structure and a second structure. The first structure includes a first base and a first qubit fixed to the first base. The second structure includes a second base, a second qubit fixed to the second base, and a first tunable coupler fixed to the second base. The first tunable coupler includes a first portion and a second portion. The first portion is capacitively coupled with the first qubit, and the second portion is capacitively coupled with the second qubit.

### CROSS-REFERENCE TO RELATED APPLICATIONS

This application is based upon and claims the benefit of priority from Japanese Patent Application No. 2023-127112, filed on Aug. 3, 2023; the entire contents of which are incorporated herein by reference.

### FIELD

Embodiments described herein relate generally to a computing device.

### BACKGROUND

For example, electronic circuits including multiple nonlinear elements are used in computing devices. Stabilization of characteristics is desired in electronic circuits and computing devices.

### BRIEF DESCRIPTION OF THE DRAWINGS

FIGS. 1A and 1B are schematic views illustrating a computing device according to a first embodiment;

FIGS. 2A and 2B are schematic cross-sectional views illustrating the computing device according to the first embodiment;

FIG. 3 is a schematic diagram illustrating the computing device according to the first embodiment;

FIG. 4 is a schematic perspective view illustrating a computing device according to the first embodiment;

FIG. 5 is a schematic perspective view illustrating a computing device according to the first embodiment;

FIGS. 6A and 6B are schematic plan views illustrating the computing device according to the first embodiment;

FIGS. 7A and 7B are schematic diagrams illustrating a computing device according to a second embodiment;

FIG. 8 is a schematic plan view illustrating a computing device according to the second embodiment;

FIG. 9 is a schematic cross-sectional view illustrating the computing device according to the second embodiment;

FIG. 10 is a schematic cross-sectional view illustrating a computing device according to the second embodiment;

FIG. 11 is a schematic cross-sectional view illustrating a computing device according to the second embodiment;

FIG. 12 is a schematic plan view illustrating a computing device according to the embodiment; and

FIG. 13 is a schematic plan view illustrating a computing device according to the embodiment.

### DETAILED DESCRIPTION

According to one embodiment, a computing device includes an element section. The element section includes a first structure and a second structure. The first structure includes a first base and a first qubit fixed to the first base. The second structure includes a second base, a second qubit fixed to the second base, and a first tunable coupler fixed to the second base. The first tunable coupler includes a first portion and a second portion. The first portion is capacitively coupled with the first qubit, and the second portion is capacitively coupled with the second qubit.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

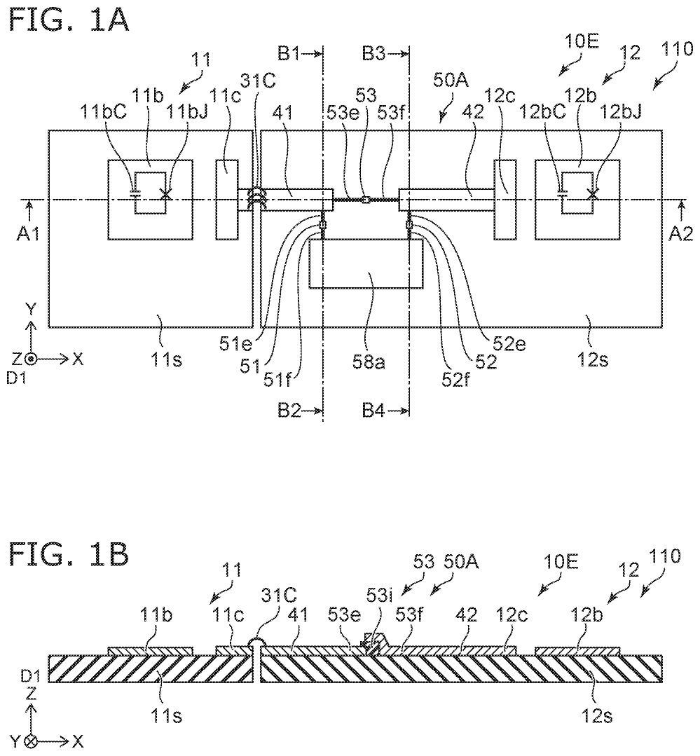

FIGS. 1A and 1B are schematic views illustrating a computing device according to a first embodiment.

FIG. 1A is a plan view. FIG. 1B is a cross-sectional view taken along the line A1-A2 of FIG. 1A.

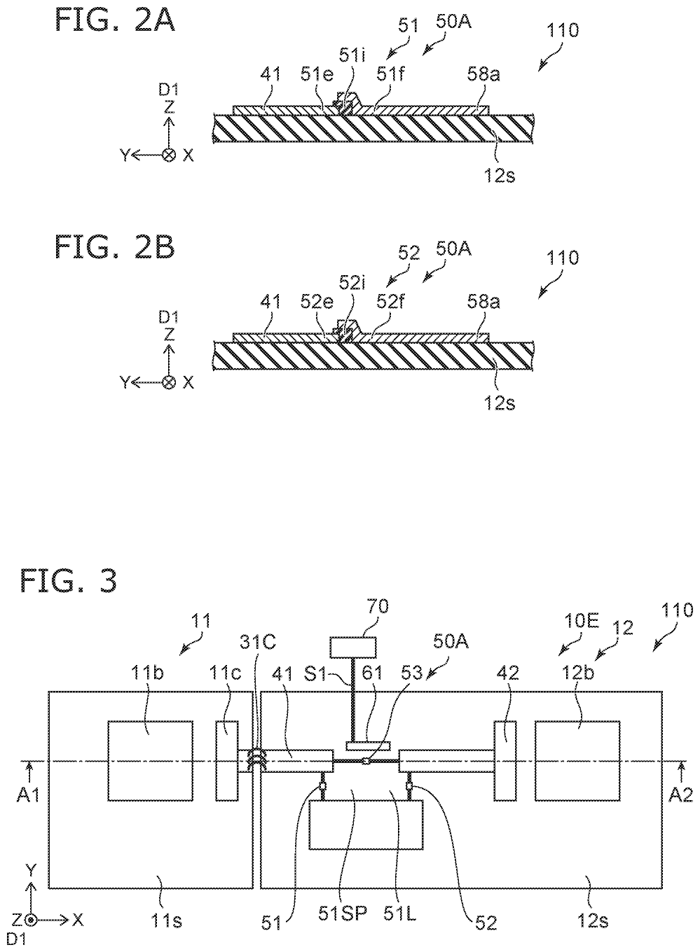

FIGS. 2A and 2B are schematic cross-sectional views illustrating the computing device according to the first embodiment.

FIG. 2A is a cross-sectional view taken along the line B1-B2 of FIG. 1A. FIG. 2B is a cross-sectional view taken along the line B3-B4 of FIG. 1A.

As shown in FIG. 1A, a computing device 110 according to the embodiment includes an element section 10E.

The element section 10E includes a first structure 11 and a second structure 12. The first structure 11 includes a first base 11s and a first qubit 11b. The first qubit 11b is fixed to the first base 11s. In one example, the first qubit 11b includes a first qubit Josephson junction 11bJ. For example, the first qubit 11b includes the first qubit Josephson junction 11bJ and a first qubit capacitor 11bC. The first qubit Josephson junction 11bJ and the first qubit capacitor 11bC are connected in parallel.

The second structure 12 includes a second base 12s, a second qubit 12b, and a first tunable coupler 50A. The second qubit 12b is fixed to the second base 12s. In one example, the second qubit 12b includes a second qubit Josephson junction 12bJ. For example, the second qubit 12b includes the second qubit Josephson junction 12bJ and a second qubit capacitor 12bC. The second qubit Josephson junction 12bJ and the second qubit capacitor 12bC are connected in parallel.

The first tunable coupler 50A is fixed to the second base 12s. The first tunable coupler 50A includes a first portion 41 and a second portion 42. The first portion 41 is capacitively coupled with the first qubit 11b. The second portion 42 is capacitively coupled with the second qubit 12b.

In the computing device 110, the first base 11s on which the first qubit 11b is provided is separated from the second base 12s on which the second qubit 12b is provided. For example, a plurality of first structures 11 are manufactured and a plurality of second structures 12 are manufactured. The plurality of first structures 11 are inspected and the plurality of first structures 11 having good characteristics are selected. The plurality of second structures 12 are inspected and the plurality of second structures 12 having good characteristics are selected. The first structure 11 having good characteristics and the second structure 12 having good characteristics are combined. Thereby, good characteristics can be stably obtained. For example, when a plurality of element sections 10E are provided, it is easy to increase the scale. A computing device capable of obtaining large-scale and stable characteristics can be easily obtained.

According to the embodiment, a computing device capable of obtaining stable characteristics can be provided.

In the computing device 110, the first qubit 11b is coupled with the second qubit 12b via the first tunable coupler 50A. The coupling strength between the first qubit 11b and the second qubit 12b is tunable. For example, stable bit operation can be performed. For example, a stable two-qubit operation can be performed.

As shown in FIG. 1A, in this example, the element section 10E further includes a first connect portion 31C. The first structure 11 further includes a first conductive portion 11c fixed to first base 11s. The first conductive portion 11c is capacitively coupled with the first qubit 11b. The first connect portion 31C electrically connects the first conductive portion 11c to the first portion 41. The first connect portion 31C is, for example, a superconductor.

As shown in FIG. 1A, in this example, the second structure 12 further includes a second conductive portion 12c. The second conductive portion 12c is electrically connected to the second portion 42. The second conductive portion 12c can be capacitively coupled with second qubit 12b. The second conductive portion 12c may be continuous with second portion 42. The boundary between the second conductive portion 12c and second portion 42 may be clear or unclear.

A first direction D1 from the first base 11s to the first qubit 11b is defined as a Z-axis direction. One direction perpendicular to the Z-axis direction is defined as an X-axis direction. A direction perpendicular to the Z-axis direction and the X-axis direction is defined as a Y-axis direction. The first base 11s is along the X-Y plane. In this example, the second base 12s is along the X-Y plane. In the embodiment, a plane parallel to the second base 12s may crosses the X-Y plane.

As shown in FIG. 1A, the first tunable coupler 50A includes a first Josephson junction 51, a second Josephson junction 52, and a third Josephson junction 53. The first Josephson junction 51 includes a first end 51e and a first other end 51f. The second Josephson junction 52 includes a second end 52e and a second other end 52f. The third Josephson junction 53 includes a third end 53e and a third other end 53f. The first end 51e is connected to the third end 53e. The first other end 51f is connected to the second other end 52f. In this example, the first other end 51f is connected to the second other end 52f via a first conductive member 58a. The second end 52e is connected to the third other end 53f. The first portion 41 is connected to the first end 51e and the third end 53e. The second portion 42 is connected to the second end 52e and the third other end 53f. The first tunable coupler 50A is, for example, a double-transmon coupler.

As shown in FIG. 1B, a third insulating member 53i is provided between a conductive member including the third end 53e and a conductive member including the third other end 53f. The region including the third insulating member 53i becomes the third Josephson junction 53.

As shown in FIG. 2A, a first insulating member 51i is provided between a conductive member including the first end 51e and a conductive member including the first other end 51f. The region including the first insulating member 51i becomes the first Josephson junction 51.

As shown in FIG. 2B, a second insulating member 52i is provided between a conductive member including the second end 52e and a conductive member including the second other end 52f. The region including the second insulating member 52i becomes the second Josephson junction 52.

FIG. 3 is a schematic diagram illustrating a computing device according to the first embodiment.

As shown in FIG. 3, the computing device 110 according to the embodiment may further include a first control conductive member 61 and a controller 70. The controller 70 is configured to supply a signal S1 to the first control conductive member 61. The signal S1 supplied to the first control conductive member 61 changes the magnetic flux of the space 51SP in the loop 51L including the first Josephson junction 51, the second Josephson junction 52, and the third Josephson junction 53. By changing the magnetic flux of the space 51SP in the loop 51L, the coupling strength between the first qubit 11b and the second qubit 12b changes.

By supplying the signal S1 to the first control conductive member 61, the controller 70 is configured to perform, for example, a two-qubit gate operation. The signal S1 is, for example, a pulse including an AC component. The frequency of the AC component included in the signal S1 is, for example, set to the difference or sum of the frequency of the first qubit and the frequency of the second qubit. In one example, the frequency of the AC component included in the signal S1 is, for example, not less than 100 MHz and not more than 1 GHz. In one example, the frequency of the AC component included in the signal S1 is, for example, not less than 8 GHz and not more than 10 GHz. In another example, the signal S1 is, for example, a pulse including a DC component.

The first control conductive member 61 may be, for example, in contact with a base (in this example, the second base 12s) in which the first tunable coupler 50A is provided. The first control conductive member 61 may be, for example, away from base in which the first tunable coupler 50A is provided.

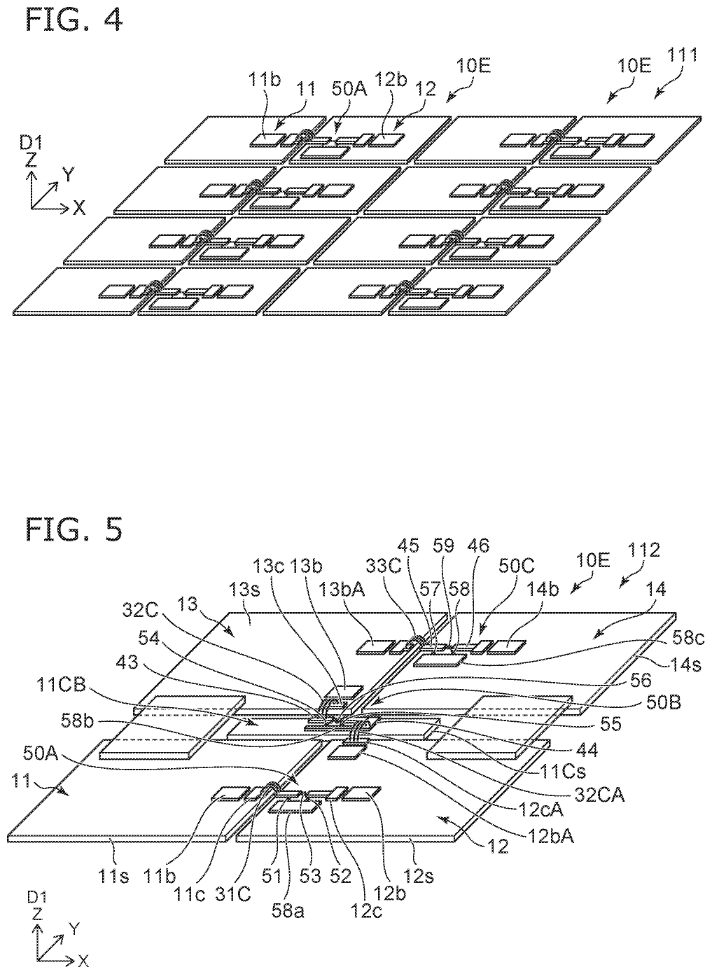

FIG. 4 is a schematic perspective view illustrating a computing device according to the first embodiment.

As shown in FIG. 4, a computing device 111 according to the embodiment includes a plurality of element sections 10E. In this example, the plurality of element sections 10E are arranged along the X-Y plane. In this embodiment, the arrangement direction of the plurality of element sections 10E is arbitrary. In the computing device 111, the configuration of each of the plurality of element sections 10E may be the same as the configuration of the element section 10E in the computing device 110.

FIG. 5 is a schematic perspective view illustrating a computing device according to the first embodiment.

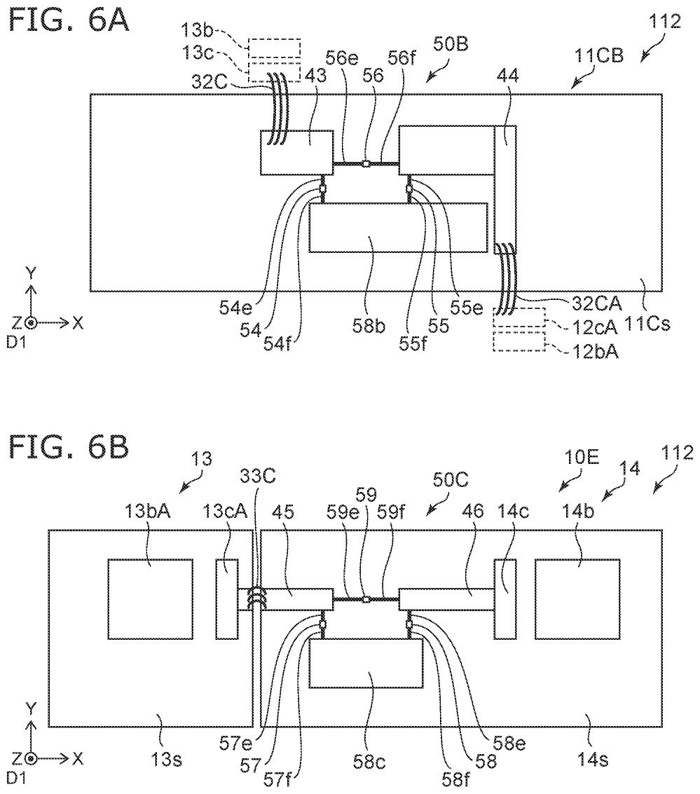

FIGS. 6A and 6B are schematic plan views illustrating the computing device according to the first embodiment.

As shown in FIG. 5, in a computing device 112 according to the embodiment, the element section 10E further includes a third structure 13 and a first connect structure 11CB. The configuration of the computing device 112 except for this may be the same as the configuration of the computing device 110.

The second structure 12 further includes a second other qubit 12bA fixed to the second base 12s. The third structure 13 includes a third base 13s and a third qubit 13b fixed to the third base 13s.

FIG. 6A illustrates the first connect structure 11CB. The first connect structure 11CB includes a first connect base 11Cs and a second tunable coupler 50B fixed to the first connect base 11Cs. The second tunable coupler 50B includes a third portion 43 and a fourth portion 44. The third portion 43 is capacitively coupled with the third qubit 13b. The fourth portion 44 is capacitively coupled with the second other qubit 12bA.

In this example, the element section 10E further includes a second opposing connect portion 32CA. The second structure 12 further includes the second opposing conductive portion 12cA fixed to the second base 12s. The second opposing conductive portion 12cA can be capacitively coupled with the second other qubit 12bA. The second opposing connect portion 32CA electrically connects the second opposing conductive portion 12cA to the fourth portion 44 (see FIG. 6A).

In this example, the element section 10E further includes the second connect portion 32C. The third structure 13 further includes the third conductive portion 13c. The third conductive portion 13c can be capacitively coupled with the third qubit 13b. The second connect portion 32C electrically connects the third conductive portion 13c to the third portion 43 (see FIG. 6A).

As shown in FIG. 6A, the second tunable coupler 50B includes a fourth Josephson junction 54, a fifth Josephson junction 55, and a sixth Josephson junction 56. The fourth Josephson junction 54 includes a fourth end 54e and a fourth other end 54f. The fifth Josephson junction 55 includes a fifth end 55e and a fifth other end 55f. The sixth Josephson junction 56 includes a sixth end 56e and a sixth other end 56f. The fourth end 54e is connected to the sixth end 56e. The fourth other end 54f is connected to the fifth other end 55f. In this example, the fourth other end 54f is connected to the fifth other end 55f via a second conductive member 58b. The fifth end 55e is connected to the sixth other end 56f. The third portion 43 is connected to the fourth end 54e and the sixth end 56e. The fourth portion 44 is connected to the fifth end 55e and the sixth other end 56f.

The second tunable coupler 50B is, for example, a double-transmon coupler.

The structure of the fourth Josephson junction 54, the fifth Josephson junction 55 and the sixth Josephson junction 56 may be the same as the structure of the first Josephson junction 51, the second Josephson junction 52 and the third Josephson junction 53. In the second tunable coupler 50B, the same structure as that of the first control conductive member 61 may be applied.

As shown in FIG. 5, in the computing device 112, the element section 10E may further include a fourth structure 14. The third structure 13 further includes a third other qubit 13bA fixed to the third base 13s. The fourth structure 14 includes a fourth base 14s, a fourth qubit 14b fixed to the fourth base 14s, and a third tunable coupler 50C fixed to the fourth base 14s. The third tunable coupler 50C includes a fifth portion 45 and a sixth portion 46. The fifth portion 45 is capacitively coupled with the third other qubit 13bA. The sixth portion 46 is capacitively coupled with the fourth qubit 14b.

In this example, the element section 10E further includes the third connect portion 33C. As shown in FIG. 6B, the third structure 13 further includes a third other conductive portion 13cA. The third other conductive portion 13cA is capacitively coupled with the third other qubit 13bA. The third connect portion 33C electrically connects the third other conductive portion 13cA to the fifth portion 45.

As shown in FIG. 6B, in this example, the fourth structure 14 further includes a fourth conductive portion 14c. The fourth conductive portion 14c is electrically connected to the sixth portion 46. The fourth conductive portion 14c can be capacitively coupled with the fourth qubit 14b. The fourth conductive portion 14c may be continuous with the sixth portion 46. The boundary between the fourth conductive portion 14c and the sixth portion 46 may be clear or unclear.

As shown in FIG. 6B, the third tunable coupler 50C includes a seventh Josephson junction 57, an eighth Josephson junction 58, and a ninth Josephson junction 59. The seventh Josephson junction 57 includes a seventh end 57e and a seventh other end 57f. The eighth Josephson junction 58 includes an eighth end 58e and an eighth other end 58f. The ninth Josephson junction 59 includes a ninth end 59e and a ninth other end 59f. The seventh end 57e is connected to the ninth end 59e. The seventh other end 57f is connected to the eighth other end 58f. In this example, the seventh other end 57f is connected to the eighth other end 58f via a third connect member 58c. The eighth end 58e is connected to the ninth other end 59f. The fifth portion 45 is connected to the seventh end 57e and the ninth end 59e. The sixth portion 46 is connected to the eighth end 58e and the ninth other end 59f. The third tunable coupler 50C is, for example, a double-transmon coupler.

The configuration of the seventh Josephson junction 57, the eighth Josephson junction 58 and the ninth Josephson junction 59 may be the same as the configuration of the first Josephson junction 51, the second Josephson junction 52 and the third Josephson junction 53. In the third tunable coupler 50C, the same configuration as that of the first control conductive member 61 may be applied.

### Second Embodiment

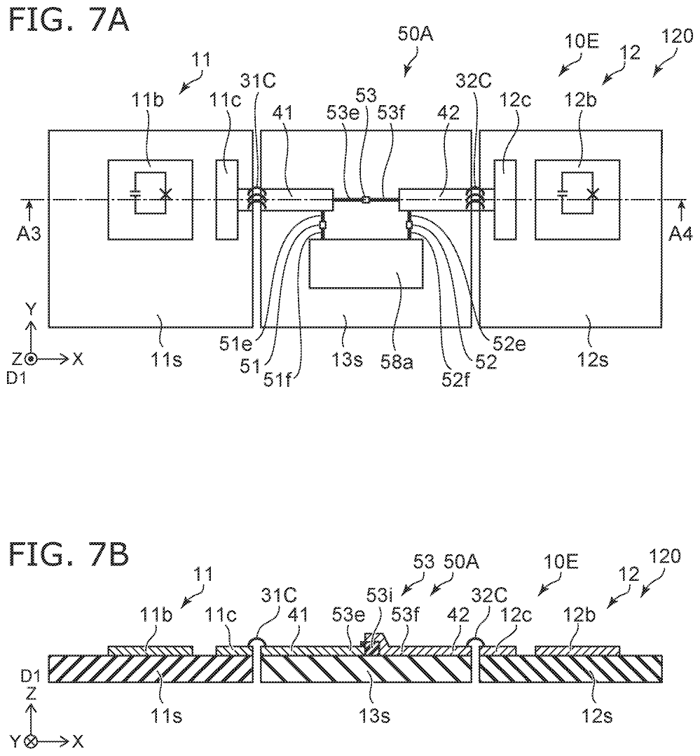

FIGS. 7A and 7B are schematic diagrams illustrating a computing device according to a second embodiment.

FIG. 7A is a plan view. FIG. 7B is a cross-sectional view taken along the line A3-A4 in FIG. 7A.

As shown in FIGS. 7A and 7B, a computing device 120 according to the embodiment includes the element section 10E.

The element section 10E includes the first structure 11, the second structure 12, and the first tunable coupler 50A. The first structure 11 includes the first base 11s and the first qubit 11b fixed to the first base 11s. The second structure 12 includes the second base 12s and the second qubit 12b fixed to the second base 12s.

The first tunable coupler 50A includes the third base 13s, the first portion 41 fixed to the third base 13s, and the second portion 42 fixed to the third base 13s. The first portion 41 is capacitively coupled with the first qubit 11b. The second portion 42 is capacitively coupled with the second qubit 12b.

In the computing device 120, for example, a plurality of first structures 11, a plurality of second structures 12 and a plurality of first tunable couplers 50A are manufactured. The plurality of first structures 11 are inspected and the plurality of first structures 11 having good characteristics are selected. The plurality of second structures 12 are inspected and the plurality of second structures 12 having good characteristics are selected. The plurality of first tunable couplers 50A are inspected and the plurality of first tunable couplers 50A having good characteristics are extracted. The first structure 11 having good characteristics, the second structure 12 having good characteristics, and the first tunable coupler 50A having good characteristics are combined.

Thereby, good characteristics can be stably obtained. For example, when a plurality of element sections 10E are provided, it is easy to increase the scale. A computing device capable of obtaining large-scale and stable characteristics is efficiently obtained. According to the embodiment, a computing device capable of obtaining stable characteristics can be provided.

In this example, the element section 10E further includes the first connect portion 31C. The first structure 11 further includes the first conductive portion 11c fixed to the first base 11s. The first conductive portion 11c is capacitively coupled with the first qubit 11b. The first connect portion 31C electrically connects the first conductive portion 11c to the first portion 41.

In this example, the element section 10E further includes the second connect portion 32C. The second structure 12 further includes the second conductive portion 12c fixed to the second base 12s. The second conductive portion 12c is capacitively coupled with the second qubit 12b. The second connect portion 32C electrically connects the second conductive portion 12c to the second portion 42.

In the computing device 120, the configuration of the first tunable coupler 50A may be the same as the configuration of the first tunable coupler 50A in the computing device 110. For example, the first tunable coupler 50A includes the first Josephson junction 51, the second Josephson junction 52, and the third Josephson junction 53 (see FIG. 7A). The first Josephson junction 51 includes the first end 51e and the first other end 51f. The second Josephson junction 52 includes the second end 52e and the second other end 52f. The third Josephson junction 53 includes the third end 53e and the third other end 53f. The first end 51e is connected to the third end 53e. The first other end 51f is connected to the second other end 52f. In this example, the first other end 51f is connected to the second other end 52f via the first conductive member 58a. The second end 52e is connected to the third other end 53f. The first portion 41 is connected to the first end 51e and the third end 53e. The second portion 42 is connected to the second end 52e and the third other end 53f. The first tunable coupler 50A is, for example, a double-transmon coupler.

In the computing device 120, the configurations of the first Josephson junction 51 and the second Josephson junction 52 may be similar to those in the computing device 110.

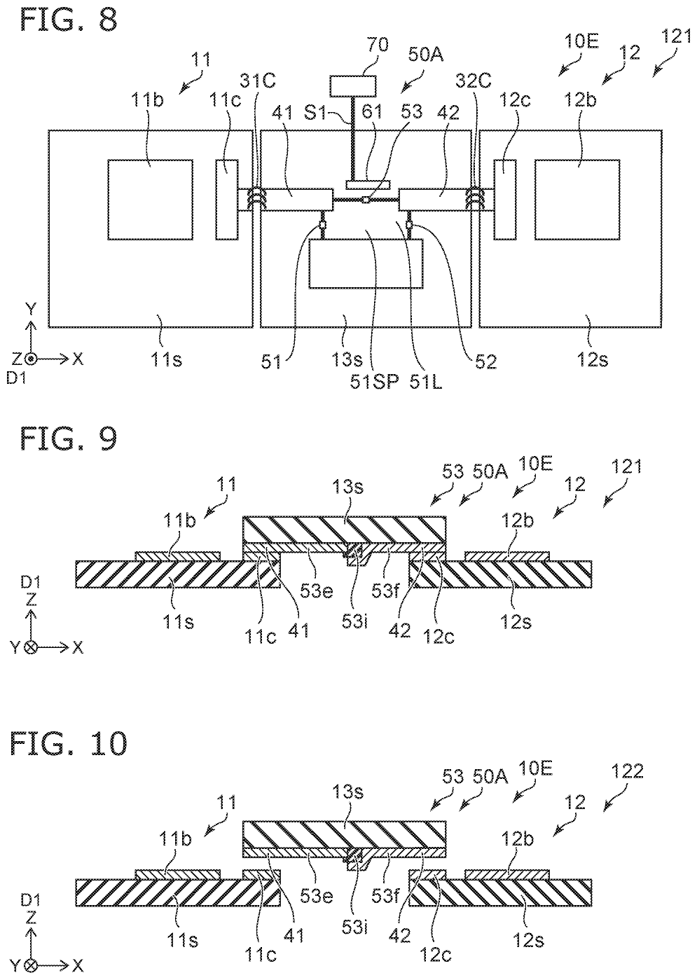

FIG. 8 is a schematic plan view illustrating a computing device according to the second embodiment.

As shown in FIG. 8, a computing device 121 according to the embodiment may further include the first control conductive member 61 and the controller 70. The controller 70 is configured to supply the signal S1 to the first control conductive member 61. The signal S1 supplied to the first control conductive member 61 changes the magnetic flux of the space 51SP in the loop 51L including the first Josephson junction 51, the second Josephson junction 52, and the third Josephson junction 53. By changing the magnetic flux of the space 51SP in the loop 51L, the coupling strength between the first qubit 11b and the second qubit 12b changes.

By supplying the signal S1 to the first control conductive member 61, the controller 70 is configured to perform, for example, a two-qubit gate operation. The signal S1 is, for example, a pulse including an AC component. The frequency of the AC component included in the signal S1 is, for example, set to the difference or sum of the frequency of the first qubit and the frequency of the second qubit. In another example, the signal S1 is, for example, a pulse including a DC component.

FIG. 9 is a schematic cross-sectional view illustrating the computing device according to the second embodiment.

As shown in FIG. 9, in the computing device 121 according to the embodiment, the first structure 11 further includes the first conductive portion 11c fixed to the first base 11s. The first conductive portion 11c can be capacitively coupled with the first qubit 11b. The first conductive portion 11c is electrically connected to the first portion 41. The second structure 12 further includes the second conductive portion 12c fixed to the second base 12s. The second conductive portion 12c is capacitively coupled with the second qubit 12b. The second conductive portion 12c is electrically connected to the second portion 42. The configuration of the computing device 121 except for the above may be the same as the configuration of the computing device 120. In the computing device 121, the first conductive portion 11c faces the first portion 41. The second conductive portion 12c faces the second portion 42.

FIG. 10 is a schematic cross-sectional view illustrating a computing device according to the second embodiment.

As shown in FIG. 10, in a computing device 122 according to the embodiment, the first structure 11 further includes the first conductive portion 11c fixed to the first base 11s. The first conductive portion 11c can be capacitively coupled with the first qubit 11b. The first conductive portion 11c can be capacitively coupled with the first portion 41. The second structure 12 further includes the second conductive portion 12c fixed to the second base 12s. The second conductive portion 12c is capacitively coupled with the second qubit 12b. The second conductive portion 12c is capacitively coupled with the second portion 42. The configuration of the computing device 122 except for the above may be the same as the configuration of the computing device 120.

In the computing device 122, the first conductive portion 11c faces the first portion 41. The second conductive portion 12c faces the second portion 42. The first conductive portion 11c is separated from the first portion 41. The second conductive portion 12c is separated from the second portion 42.

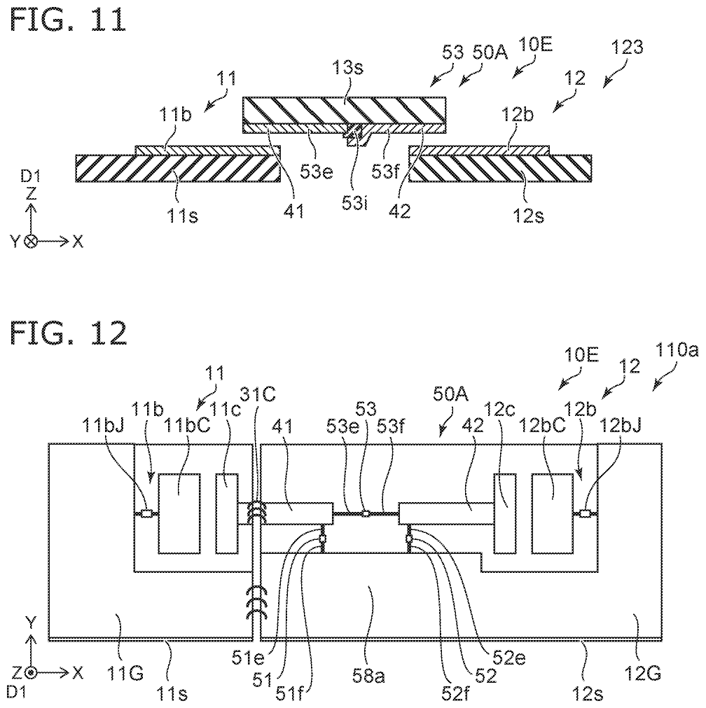

FIG. 11 is a schematic cross-sectional view illustrating a computing device according to the second embodiment.

As shown in FIG. 11, in a computing device 123 according to the embodiment, the first qubit 11b faces the first portion 41. The first qubit 11b is capacitively coupled with the first portion 41. The second qubit 12b faces the second portion 42. The second qubit 12b is capacitively coupled with the second portion 42. The configuration of the computing device 123 except for the above may be the same as the configuration of the computing device 120.

A good characteristic is stably obtained in the computing device 121, the computing device 122 and the computing device 123. For example, it is easy to increase the size. A computing device capable of obtaining large-scale and stable characteristics is effectively obtained. According to the embodiment, a computing device capable of obtaining stable characteristics can be provided.

In the configuration of the computing device 120, the computing device 121, the computing device 122 and the computing device 123, a plurality of element sections 10E may be provided.

FIG. 12 is a schematic plan view illustrating a computing device according to the embodiment.

As shown in FIG. 12, in a computing device 110a according to the embodiment, the first structure 11 includes a first conductive layer 11G. The second structure 12 includes a second conductive layer 12G. The configuration of the computing device 110a except for the above may be the same as the configuration of the computing device 110.

The first conductive layer 11G is provided on the first base 11s. The first conductive layer 11G functions as a ground layer, for example. The first conductive layer 11G may function as a part of the first qubit 11b, for example. The second conductive layer 12G is provided on the second base 12s. The second conductive layer 12G functions as a ground layer, for example. The second conductive layer 12G may function as a part of the second qubit 12b, for example. The first conductive layer 11G is electrically connected to the first conductive member 58a.

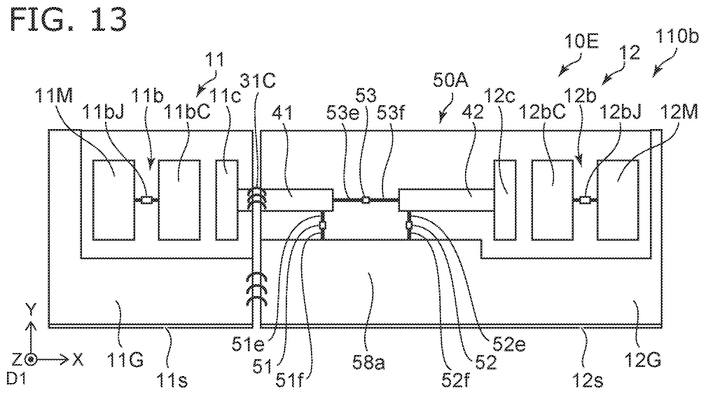

FIG. 13 is a schematic plan view illustrating a computing device according to the embodiment.

As shown in FIG. 13, in the computing device 110b according to the embodiment, the first structure 11 includes a first intermediate conductive layer 11M. The second structure 12 includes a second intermediate conductive layer 12M. The configuration of the computing device 110b except for the above may be the same as the configuration of the computing device 110a.

The first intermediate conductive layer 11M is provided on the first base 11s. The first intermediate conductive layer 11M functions as a ground layer, for example. The first intermediate conductive layer 11M may function as a part of the first qubit 11b, for example. The first intermediate conductive layer 11M is capacitively coupled with the first conductive layer 11G. The first conductive layer 11G is electrically connected to the first conductive member 58a.

The second intermediate conductive layer 12M is provided on the second base 12s. The second intermediate conductive layer 12M functions as a ground layer, for example. The second intermediate conductive layer 12M may function as a part of the second qubit 12b, for example. The second intermediate conductive layer 12M is capacitively coupled with the second conductive layer 12G. The second conductive layer 12G is continuous with the first conductive member 58a.

The first conductive layer 11G and the second conductive layer 12G may be applied to the second embodiment. The first intermediate conductive layer 11M and the second intermediate conductive layer 12M may be applied to the second embodiment.

The embodiment may include the following Technical proposals:

### Technical Proposal 1

A computing device, comprising:
an element section, the element section including
   a first structure including a first base and a first qubit fixed to the first base,
   a second structure including a second base, a second qubit fixed to the second base, and a first tunable coupler fixed to the second base, the first tunable coupler including a first portion and a second portion, the first portion being capacitively coupled with the first qubit, the second portion being capacitively coupled with the second qubit.

### Technical Proposal 2

The computing device according to Technical proposal 1, wherein
the first tunable coupler includes a first Josephson junction, a second Josephson junction, and a third Josephson junction,
the first Josephson junction includes a first end and a first other end,
the second Josephson junction includes a second end and a second other end,
the third Josephson junction includes a third end and a third other end,
the first end is connected to the third end,
the first other end is connected to the second other end,
the second end is connected to the third other end,
the first portion is connected to the first end and the third end, and
the second portion is connected to the second end and the third other end.

### Technical Proposal 3

The computing device according to Technical proposal 1 or 2, wherein
the element section further includes a first connect portion,
the first structure further includes a first conductive portion fixed to the first base,
the first conductive portion is capacitively coupled with the first qubit, and
the first connect portion electrically connects the first conductive portion to the first portion.

### Technical Proposal 4

The computing device according to Technical proposal 3, wherein
the second structure further includes a second conductive portion,
the second conductive portion is electrically connected to the second portion, and
the second conductive portion is capacitively coupled with the second qubit.

### Technical Proposal 5

The computing device according to any one of the Technical proposals 1-3, wherein
the element section further includes a third structure and a first connect structure,
the second structure further includes a second other qubit fixed to the second base,
the third structure includes a third base and a third qubit fixed to the third base,
the first connect structure includes a first connect base and a second tunable coupler fixed to the first connect base,
the second tunable coupler includes a third portion and a fourth portion,
the third portion is capacitively coupled with the third qubit, and
the fourth portion is capacitively coupled with the second other qubit.

### Technical Proposal 6

The computing device according to Technical proposal 5, wherein
the second tunable coupler includes a fourth Josephson junction, a fifth Josephson junction, and a sixth Josephson junction,
the fourth Josephson junction includes a fourth end and a fourth other end,
the fifth Josephson junction includes a fifth end and a fifth other end,
the sixth Josephson junction includes a sixth end and a sixth other end,
the fourth end is connected to the sixth end,
the fourth other end is connected to the fifth other end,
the fifth end is connected to the sixth other end,
the third portion is connected to the fourth end and the sixth end, and
the fourth portion is connected to the fifth end and the sixth other end.

### Technical Proposal 7

The computing device according to Technical proposal 5 or 6, wherein
the element section further includes a second opposing connect portion,
the second structure further includes a second opposing conductive portion fixed to the second base,
the second opposing conductive portion is capacitively coupled with the second other qubit, and
the second opposing connect portion electrically connects the second opposing conductive portion to the fourth portion.

### Technical Proposal 8

The computing device according to any one of Technical proposals 5-7, wherein
the element section further includes a second connect portion,
the third structure further includes a third conductive portion,
the third conductive portion is capacitively coupled with the third qubit, and
the second connect portion electrically connects the third conductive portion to the third portion.

### Technical Proposal 9

The computing device according to any one of Technical proposals 5-8, wherein
the element section further includes a fourth structure,
the third structure further includes a third other qubit fixed to the third base,
the fourth structure includes a fourth base, a fourth qubit fixed to the fourth base, and a third tunable coupler fixed to the fourth base,
the third tunable coupler includes a fifth portion and a sixth portion,
the fifth portion is capacitively coupled with the third other qubit, and
the sixth portion is capacitively coupled with the fourth qubit.

### Technical Proposal 10

The computing device according to Technical proposal 9, wherein
the third tunable coupler includes a seventh Josephson junction, an eighth Josephson junction, and a ninth Josephson junction,
the seventh Josephson junction includes a seventh end and a seventh other end,
the eighth Josephson junction includes an eighth end and an eighth other end,
the ninth Josephson junction includes a ninth end and a ninth other end,
the seventh end is connected to the ninth end,
the seventh other end is connected to the eighth other end,
the eighth end is connected to the ninth other end,
the fifth portion is connected to the seventh end and the ninth end, and
the sixth portion is connected to the eighth end and the ninth other end.

### Technical Proposal 11

A computing device, comprising:
an element section, the element section including
a first structure including a first base and a first qubit fixed to the first base,
a second structure including a second base and a second qubit fixed to the second base, and
a first tunable coupler including a third base, a first portion fixed to the third base, and a second portion fixed to the third base, the first portion being capacitively couplable with the first qubit, the second portion being capacitively couplable with the second qubit.

### Technical Proposal 12

The computing device according to Technical proposal 11, wherein
the first tunable coupler includes a first Josephson junction, a second Josephson junction, and a third Josephson junction,
the first Josephson junction includes a first end and a first other end,
the second Josephson junction includes a second end and a second other end,
the third Josephson junction includes a third end and a third other end,
the first end is connected to the third end,
the first other end is connected to the second other end,
the second end is connected to the third other end,
the first portion is connected to the first end and the third end, and
the second portion is connected to the second end and the third other end.

### Technical Proposal 13

The computing device according to Technical proposal 11 or 12, wherein
the element section further includes a first connect portion,
the first structure further includes a first conductive portion fixed to the first base,
the first conductive portion is capacitively coupled with the first qubit, and
the first connect portion electrically connects the first conductive portion to the first portion.

### Technical Proposal 14

The computing device according to Technical proposal 13, wherein
the element section further includes a second connect portion,
the second structure further includes a second conductive portion fixed to the second base,
the second conductive portion is capacitively coupled with the second qubit, and
the second connect portion electrically connects the second conductive portion to the second portion.

### Technical Proposal 15

The computing device according to Technical proposal 11 or 12, wherein
the first structure further includes a first conductive portion fixed to the first base,
the first conductive portion is capacitively coupled with the first qubit,
the first conductive portion is electrically connected to the first portion,
the second structure further includes a second conductive portion fixed to the second base,
the second conductive portion is capacitively coupled with the second qubit, and
the second conductive portion is electrically connected to the second portion.

### Technical Proposal 16

The computing device according to Technical proposal 11 or 12, wherein
the first structure further includes a first conductive portion fixed to the first base,
the first conductive portion is capacitively coupled with the first qubit,
the first conductive portion is capacitively coupled with the first portion,
the second structure further includes a second conductive portion fixed to the second base,
the second conductive portion is capacitively coupled with the second qubit, and
the second conductive portion is capacitively coupled with the second portion.

### Technical Proposal 17

The computing device according to Technical proposal 15 or 16, wherein
the first conductive portion faces the first portion, and
the second conductive portion faces the second portion.

### Technical Proposal 18

The computing device according to Technical proposal 2, further comprising:
a first control conductive member; and
a controller,
the controller being configured to supply a signal to the first control conductive member, and
a magnetic flux in a space in a loop including the first Josephson junction, the second Josephson junction, and the third Josephson junction being configured to change by the signal supplied to the first control conductive member.

### Technical Proposal 19

The computing device according to Technical proposal 18, wherein
the signal includes an alternating component.

### Technical Proposal 20

The computing device according to Technical proposal 18 or 19, wherein
the controller is configured to perform a two-qubit operation by supplying the signal to the first control conductive member.

According to the embodiment, an electronic circuit and a computing device capable of improving characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the computing devices such as bases, qubits, tunable couplers, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all computing devices practicable by an appropriate design modification by one skilled in the art based on the computing devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A computing device, comprising:
an element section, the element section including
a first structure including a first base and a first qubit fixed to the first base,
a second structure including a second base, a second qubit fixed to the second base, and a first tunable coupler fixed to the second base, the first tunable coupler including a first portion and a second portion, the first portion being capacitively coupled with the first qubit, the second portion being capacitively coupled with the second qubit.

2. The device according to claim 1, wherein
the first tunable coupler includes a first Josephson junction, a second Josephson junction, and a third Josephson junction,
the first Josephson junction includes a first end and a first other end,
the second Josephson junction includes a second end and a second other end,
the third Josephson junction includes a third end and a third other end,
the first end is connected to the third end,
the first other end is connected to the second other end,
the second end is connected to the third other end,
the first portion is connected to the first end and the third end, and
the second portion is connected to the second end and the third other end.

3. The device according to claim 1, wherein
the element section further includes a first connect portion,
the first structure further includes a first conductive portion fixed to the first base,
the first conductive portion is capacitively coupled with the first qubit, and
the first connect portion electrically connects the first conductive portion to the first portion.

4. The device according to claim 3, wherein
the second structure further includes a second conductive portion,
the second conductive portion is electrically connected to the second portion, and
the second conductive portion is capacitively coupled with the second qubit.

5. The device according to claim 1, wherein
the element section further includes a third structure and a first connect structure,
the second structure further includes a second other qubit fixed to the second base,
the third structure includes a third base and a third qubit fixed to the third base,
the first connect structure includes a first connect base and a second tunable coupler fixed to the first connect base,
the second tunable coupler includes a third portion and a fourth portion,
the third portion is capacitively coupled with the third qubit, and
the fourth portion is capacitively coupled with the second other qubit.

6. The device according to claim 5, wherein
the second tunable coupler includes a fourth Josephson junction, a fifth Josephson junction, and a sixth Josephson junction,
the fourth Josephson junction includes a fourth end and a fourth other end,
the fifth Josephson junction includes a fifth end and a fifth other end,
the sixth Josephson junction includes a sixth end and a sixth other end,
the fourth end is connected to the sixth end,
the fourth other end is connected to the fifth other end,
the fifth end is connected to the sixth other end,
the third portion is connected to the fourth end and the sixth end, and
the fourth portion is connected to the fifth end and the sixth other end.

7. The device according to claim 5, wherein
the element section further includes a second opposing connect portion,
the second structure further includes a second opposing conductive portion fixed to the second base,
the second opposing conductive portion is capacitively coupled with the second other qubit, and
the second opposing connect portion electrically connects the second opposing conductive portion to the fourth portion.

8. The device according to claim 5, wherein
the element section further includes a second connect portion,
the third structure further includes a third conductive portion,
the third conductive portion is capacitively coupled with the third qubit, and
the second connect portion electrically connects the third conductive portion to the third portion.

9. The device according to claim 5, wherein
the element section further includes a fourth structure,
the third structure further includes a third other qubit fixed to the third base,
the fourth structure includes a fourth base, a fourth qubit fixed to the fourth base, and a third tunable coupler fixed to the fourth base,
the third tunable coupler includes a fifth portion and a sixth portion,
the fifth portion is capacitively coupled with the third other qubit, and
the sixth portion is capacitively coupled with the fourth qubit.

10. The device according to claim 9, wherein
the third tunable coupler includes a seventh Josephson junction, an eighth Josephson junction, and a ninth Josephson junction,
the seventh Josephson junction includes a seventh end and a seventh other end,
the eighth Josephson junction includes an eighth end and an eighth other end,
the ninth Josephson junction includes a ninth end and a ninth other end,
the seventh end is connected to the ninth end,
the seventh other end is connected to the eighth other end,
the eighth end is connected to the ninth other end,
the fifth portion is connected to the seventh end and the ninth end, and
the sixth portion is connected to the eighth end and the ninth other end.

11. A computing device, comprising:
an element section, the element section including
a first structure including a first base and a first qubit fixed to the first base,
a second structure including a second base and a second qubit fixed to the second base, and
a first tunable coupler including a third base, a first portion fixed to the third base, and a second portion fixed to the third base, the first portion being capacitively couplable with the first qubit, the second portion being capacitively couplable with the second qubit.

12. The device according to claim 11, wherein
the first tunable coupler includes a first Josephson junction, a second Josephson junction, and a third Josephson junction,
the first Josephson junction includes a first end and a first other end,
the second Josephson junction includes a second end and a second other end,
the third Josephson junction includes a third end and a third other end,
the first end is connected to the third end,
the first other end is connected to the second other end,
the second end is connected to the third other end,
the first portion is connected to the first end and the third end, and
the second portion is connected to the second end and the third other end.

13. The device according to claim 11, wherein
the element section further includes a first connect portion,
the first structure further includes a first conductive portion fixed to the first base,
the first conductive portion is capacitively coupled with the first qubit, and
the first connect portion electrically connects the first conductive portion to the first portion.

14. The device according to claim 13, wherein
the element section further includes a second connect portion,
the second structure further includes a second conductive portion fixed to the second base,
the second conductive portion is capacitively coupled with the second qubit, and
the second connect portion electrically connects the second conductive portion to the second portion.

15. The device according to claim 11, wherein
the first structure further includes a first conductive portion fixed to the first base,
the first conductive portion is capacitively coupled with the first qubit,
the first conductive portion is electrically connected to the first portion,
the second structure further includes a second conductive portion fixed to the second base,
the second conductive portion is capacitively coupled with the second qubit, and
the second conductive portion is electrically connected to the second portion.

16. The device according to claim 11, wherein
the first structure further includes a first conductive portion fixed to the first base,
the first conductive portion is capacitively coupled with the first qubit,
the first conductive portion is capacitively coupled with the first portion,
the second structure further includes a second conductive portion fixed to the second base,
the second conductive portion is capacitively coupled with the second qubit, and
the second conductive portion is capacitively coupled with the second portion.

17. The device according to claim 15, wherein
the first conductive portion faces the first portion, and
the second conductive portion faces the second portion.

18. The device according to claim 2, further comprising:
a first control conductive member; and
a controller,
the controller being configured to supply a signal to the first control conductive member, and
a magnetic flux in a space in a loop including the first Josephson junction, the second Josephson junction, and the third Josephson junction being configured to change by the signal supplied to the first control conductive member.

19. The device according to claim 18, wherein
the signal includes an alternating component.

20. The device according to claim 18, wherein
the controller is configured to perform a two-qubit operation by supplying the signal to the first control conductive member.
